(19) United States
(12) Patent Application Publication
(10) Pub. No.: US 2004/0222736 A1
(43) Pub. Date: Nov. 11, 2004

(54) Electroluminescent display device

(75) Inventor: Kiyoshi Yoneda, Mizuho-shi (JP)

Correspondence Address: MORRISON & FOERSTER LLP, 1650 TYSONS BOULEVARD, SUITE 300, MCLEAN, VA, 22102, US

(73) Assignee: Sanyo Electric Co., Ltd., Moriguchi-city (JP)

(21) Appl. No.: 10/790,247

(22) Filed: Mar. 2, 2004

(30) Foreign Application Priority Data
Mar. 3, 2003 (JP) 2003-055333
Feb. 5, 2004 (JP) 2004-028951

(51) Int. Cl. H05B 33/00; H05B 33/14

(52) U.S. Cl. 313/503; 313/502; 313/506; 428/917

(57) ABSTRACT

The invention is directed to an increase of luminous efficiency of a white organic EL element. A white emissive layer of an organic EL element is formed by laminating a blue emissive layer and a yellow emissive layer. The blue emissive layer emitting blue light having a short wavelength is formed on a side nearer to the anode layer, and the yellow emissive layer emitting yellow light having a longer wavelength than the blue emissive layer is disposed on the blue emissive layer. Under this configuration, the blue light emitted from the blue emissive layer reaches the color filter layer without penetrating through the yellow emissive layer. On the other hand, the yellow light emitted from the yellow emissive layer penetrates through the blue emissive layer. The yellow light has a longer wavelength than the blue light, an absorption amount of the yellow light becomes relatively small. An absorption amount of the blue light also reduces, so that the luminous efficiency increases.

### BACKGROUND OF THE INVENTION

1. Field of the Invention

The invention relates to an electroluminescent display device, particularly having a white emissive layer emitting white light.

2. Description of the Related Art

An organic electroluminescent (hereafter, referred to as EL) element is a self-emissive element. In recent years, an organic EL display device using the organic EL elements has been receiving attention as a new display device substituted for a CRT or an LCD.

FIG. 7 is a schematic cross-sectional view of a pixel of a full-color organic EL display device of a conventional art. A numeral 200 designates a glass substrate, a numeral 201 designates an organic EL element driving TFT (thin film transistor) formed on the glass substrate 200, and a numeral 202 designates a first planarization insulating film. A numeral 203 designates an anode layer made of ITO (indium tin oxide) which is connected with the TFT 201 and extends over the first planarization insulating film 202, and a numeral 204 designates a second planarization insulating film formed so as to cover end portions of the anode layer 203. A numeral 205 designates R (red), G (green), and B (blue) organic EL layers each formed on the anode layer 203, and a numeral 206 designates a cathode layer formed on the organic EL layers 205.

A glass substrate 207 covers the cathode layer 206. The glass substrate 207 and the glass substrate 200 are attached at those edges to enclose the R, G, and B organic EL layers 205 therein. Here, the R, G, and B organic EL layers 205 are respectively formed by selectively performing vapor-deposition of organic EL materials which emit each of R, G, and B lights by using a metal mask.

On the other hand, as a method of realizing a full-color organic EL display device without providing the R, G, and B organic EL layers 205, a combination of a white emissive layer emitting white light and color filter layers has been proposed. Such a structure is described, for example, Japanese Patent Application Publication No. Hei 8-321380. The characteristics of this structure is that a plurality of emissive layers are combined to generate white light.

### SUMMARY OF THE INVENTION

The invention provides an electroluminescent display device that includes a plurality of pixels, an anode layer provided for each of the pixels, and an electroluminescent layer provided for each of the pixels and disposed above a corresponding anode layer. The electroluminescent layer includes a first emissive layer of a first wavelength and a second emissive layer of a second wavelength that is longer than the first wavelength, and the first emissive layer is disposed closer to the anode layer than the second emissive layer. The device also includes a cathode layer disposed above the electroluminescent layers.

The invention also provides an electroluminescent display device that includes an insulating substrate, a plurality of pixels disposed on the insulating substrate, and a color filter layer provided for each of the pixels. The color filter layers are disposed above the insulating substrate. The device also includes an anode layer made of a transparent electrode, provided for each of the pixels and disposed above a corresponding color filter layer, and an electroluminescent layer provided for each of the pixels and disposed above a corresponding anode layer. The electroluminescent layer includes a plurality of emissive layers each emitting light of a different wavelength. The emissive layers are disposed so that an emissive layer emitting light of a shorter wavelength is disposed closer to the anode layer than an emissive layer emitting light of a longer wavelength. The device also includes a cathode layer disposed above the electroluminescent layers.

### BRIEF DESCRIPTION OF THE DRAWINGS

FIG. 1 is a cross-sectional view of an organic EL display device of a first embodiment of the invention.

FIG. 2 is a plan view of an organic EL display device of the first embodiment.

FIG. 3 is a cross-sectional view along line A-A of FIG. 2.

FIG. 4 is a cross-sectional view along line B-B of FIG. 2.

FIG. 5 is a cross-sectional view of an organic EL display device of a second embodiment of the invention.

FIG. 6 is a cross-sectional view of an organic EL display device of a third embodiment of the invention.

FIG. 7 is a cross-sectional view of an organic EL display device of a conventional art.

### DESCRIPTION OF THE PREFERRED EMBODIMENTS

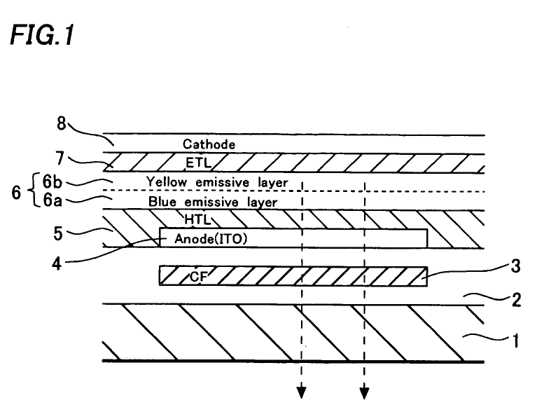

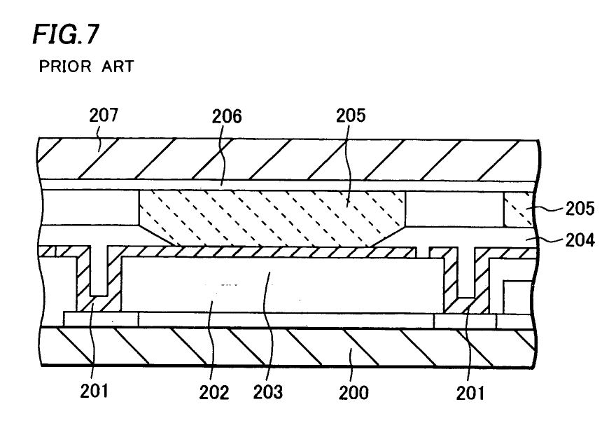

FIG. 1 is a cross-sectional view of an organic EL display device of a first embodiment of the invention. An insulating film 2 made of SiO₂ is formed on a glass substrate 1, and a color filter layer 3 is formed in the insulating film 2. An anode layer 4 made of ITO and serving as a transparent electrode is formed above the color filter layer 3. On the anode layer 4, an electron transport layer (HTL) 5, a white emissive layer ‘6, a hole transport layer 7, a cathode layer 8 made of Al (aluminum) are laminated in this order. FIG. 1 shows only an organic EL element and a color filter layer in a pixel, and other components including an organic EL element driving TFT and a pixel selecting TFT, such as those shown in FIG. 7, are omitted.

When an electric current flows from the anode layer 4 to the cathode layer 8 through an organic EL element driving TFT (not shown in FIG. 1), white light is generated from the white emissive layer 6, and emitted outside through the anode layer 4, the color filter layer 3, and the glass substrate 1. Accordingly, a full-color display can be obtained by forming the R, G, and B color filter layers 3 in each of the pixels.

In this organic EL display device, the white emissive layer 6 is formed by laminating the blue emissive layer 6a and the yellow emissive layer 6b. The blue emissive layer 6a emitting blue light having a short wavelength is formed on the side closer to an anode layer 4 than the yellow emissive layer 6b, and the yellow emissive layer 6b emitting yellow light having a longer wavelength than the blue light is disposed on the blue emissive layer 6a. Under this configuration, blue light emitted from the blue emissive layer 6a reaches the color filter layer 3 without penetrating through the yellow emissive layer 6b, and is emitted outside through the color filter layer 3. On the other hand, yellow light emitted from the yellow emissive layer 6b penetrates through the blue emissive layer 6a and then the color filter layer 3. Since the yellow light has a longer wavelength than the blue light, the absorption amount of the yellow light is relatively small. The absorption amount of the blue light also reduces so that the luminous efficiency increases.

On the contrary, if the yellow emissive layer 6b and the blue emissive layer 6a are formed above the anode layer 4 in this order, blue light emitted from the blue emissive layer 6a reaches the color filter layer 3 mainly through the yellow emissive layer 6b, the electron transport layer 5 and the anode layer 4. In this configuration, since the blue light has the shorter wavelength, it is easily absorbed in the above intermediate layers before reaching the color filter layer 3. This results in a problem of lowering luminous efficiency.

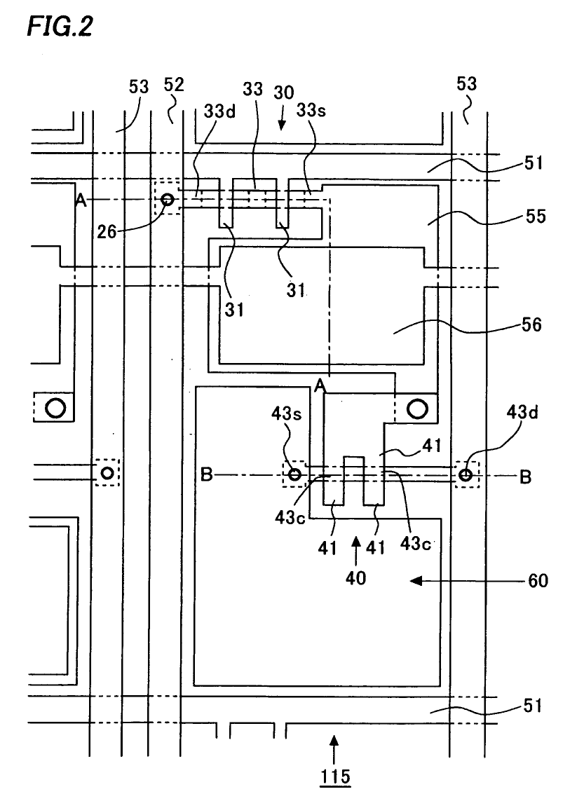

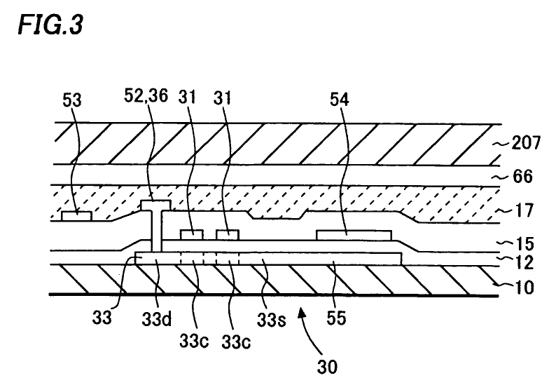

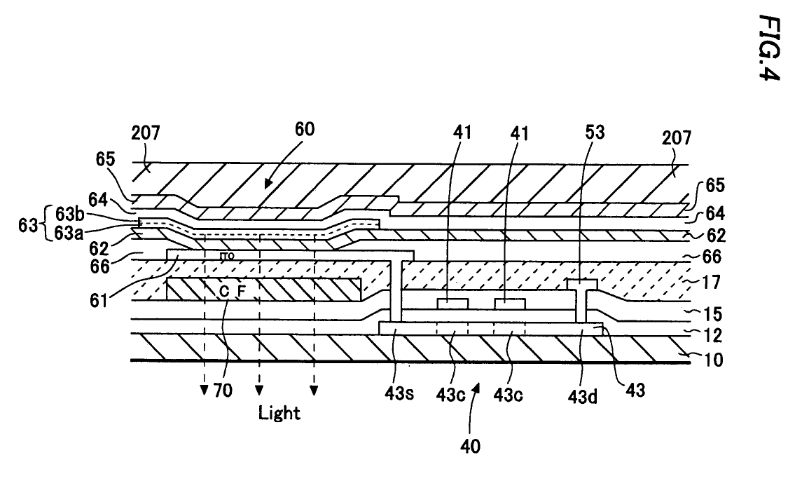

Next, a structure of the organic EL display device will be described based on the first embodiment in detail. FIG. 2 is a plan view of a pixel of the organic EL display device. FIG. 3 is a cross-sectional view along line A-A of FIG. 2, and FIG. 4 is a cross-sectional view along line B-B of FIG. 2.

A pixel 115 is formed in a region enclosed with a gate signal line 51 and a drain signal line 52. A plurality of the pixels 115 is disposed in a matrix.

An organic EL element 60 as a self-emissive element, a switching TFT (thin film transistor) 30 for controlling a timing of supplying an electric current to the organic EL element 60, a driving TFT 40 for supplying an electric current to the organic EL element 60, and a storage capacitor 56 are placed in the pixel 115. The organic EL element 60 is formed of an anode layer 61, a white emissive layer 63 made of a white emissive material, and a cathode layer 65. A structure of the white emissive layer 63 will be described below.

The switching TFT 30 is provided on a periphery of an intersection of the signal lines 51 and 52. A source 33s of the switching TFT 30 serves as a capacitor electrode 55 for forming a capacitor with a storage capacitor electrode line 54 (56?) and is connected with a gate electrode 41 of the driving TFT 40. A source 43s of the driving TFT 40 is connected with the anode layer 61 of the organic EL element 60, while a drain 43d is connected with a driving source line 53 as a source of a current to be supplied to the organic EL element 60.

A cross-sectional structure of the organic EL display device will be described with reference to FIGS. 3 and 4. A structure of the switching TFT 30 will be described first. As shown in FIG. 3, an amorphous silicon film (hereafter, referred to as an a-Si film) is formed on a transparent insulating substrate 10 made of a silica glass or a non-alkali glass by a CVD method and so on. The a-Si film is irradiated with laser beams for melting and recrystalizing to form a poly-silicon film (hereafter, referred to as a p-Si film) as an active layer 33.

On the active layer 33, a single-layer or a multi-layer of an SiO₂ film and an SiNₓ film is formed as a gate insulating film 12. There are disposed on the gate insulating film 12 the gate signal line 51 made of metal having a high melting point such as Cr (chromium) or Mo (molybdenum) and also serving as a gate electrode 31, the drain signal line 52 made of Al (aluminum), and the driving source line 53 made of Al and serving as a driving source of the organic EL element 60.

An interlayer insulating film 15 formed by laminating an SiO₂ film, an SiNₓ film and an SiO₂ film sequentially is placed on the whole surfaces of the gate insulating film 12 and the active layer 33. A drain electrode 36 is provided by filling a contact hole provided corresponding to a drain 33d with metal such as Al. Furthermore, a first planarization insulating film 17 for planarizing a surface, which is made of organic resin, is formed on the whole surface.

Next, a structure of the driving TFT 40 will be described. As shown in FIG. 4, an active layer 43 formed by poly-crystalizing an a-Si film by radiating laser beams thereto, the gate insulating film 12, and the gate electrode 41 made of metal having a high melting point such as Cr or Mo are formed sequentially on the transparent insulating substrate 10 made of a silica glass, or a non-alkali glass.

A channel 43c, a source 43s, and a drain 43d are provided in the active layer 43, the source 43s and the drain 43d being placed on both sides of the channel 43c. The interlayer insulating film 15 formed by laminating an SiO₂ film, an SiNₓ film and an SiO₂ film sequentially is placed on the whole surfaces of the gate insulating film 12 and the active layer 43. The driving source line 53 connected with a driving source is provided by filling a contact hole provided corresponding to the drain 43d with a metal such as Al.

A color filter layer 70 is formed on the interlayer insulating film 15 adjacently to the driving TFT 40. The color filter layer 70 is formed in each of the pixels, having spectral characteristics of R, G or B color. For example, a pixel R includes a color filter layer 70 having spectral characteristics of red.

Furthermore, the planarization insulating film 17 for planarizing a surface, which is made of, for example, an organic resin, is formed on a the whole surface. A contact hole is formed in a position corresponding to the source 43s in the planarization insulating film 17. The anode layer 61 of the organic EL element, which is an transparent electrode made of ITO and is in contact with the source 43s through the contact hole, is formed on the planarization insulating film 17. The anode layer 61 is formed above the color filter layer 70 in each of the pixels, being isolated as an island.

A second planarization insulating film 66 is further formed on the first planarization insulating film 17, covering end portions of the anode layer 61. The second planarization insulating film 66 is removed on the light-emitting region of the anode layer 61.

The organic EL element 60 is formed by laminating the anode layer 61 made of a transparent electrode such as ITO, a hole transport layer 62 made of NPB, an white emissive layer 63, an electron transport layer 64 made of Alq³ (8-tris-hydroxyquinoline aluminum) and the cathode layer 65 made of magnesium-indium alloy, Al or Al alloy, in this order. The white emissive layer 63 is formed by laminating a blue emissive layer 63a and a yellow emissive layer 63b. The blue emissive layer 63a is disposed on the side closer to the anode layer 61 than the yellow emissive layer 63b. The blue emissive layer 63a is made of Zn (BOX)² which is an abbreviation for bis ((2-hydroxyphenyl) benzoxazole) zinc. The yellow emissive layer 63b is formed by adding rubrene as yellow dopant to an NPB (host). The NPB (host) is an abbreviation for N, N′-Di (naphthalene-1-yl)-N, N′-diphenyl-benzidine. The cathode layer 65 is covered with the glass substrate 207.

In the organic EL element 60, a hole injected from the anode layer 61 and an electron injected from the cathode layer 65 are recombined in the white emissive layer 63, and excitons are formed by exciting organic molecules forming the white emissive layer 63. Blue light and yellow light are emitted from the white emissive layer 63 in a process of radiation of the excitons, combined to be white light, and then released outside after penetrating through the transparent anode layer 61 and the transparent insulating substrate 10, thereby completing a light-emission.

Since the blue emissive layer 63a is placed on the side closer to the anode layer 61 than the yellow emissive layer 63b, the blue light emitted from the blue emissive layer 63a reaches the color filter layer 70 through the hole transport layer 62, the anode layer 61 and the first planarization insulating film 17. Then, the blue light is filtered through the color filter layer 70 and emitted outside through the insulating substrate 10.

The blue light emitted from the blue emissive layer 63a reaches the color filter layer 70 without passing through the yellow emissive layer 63b and is emitted outside through the color filter layer 70. On the other hand, the yellow light emitted from the yellow emissive layer 63b passes through the blue emissive layer 63a and then the color filter layer 70. Since the yellow light has a longer wavelength than the blue light, the absorption amount of the yellow light is relatively small. The absorption amount of the blue light also reduces so that the luminous efficiency is improved.

Next, other embodiments will be described with reference to the drawings in detail. FIG. 5 is a cross-sectional view of the organic EL display device based on the second embodiment. FIG. 5 shows only an organic EL element and a color filter layer in a pixel, and other components including an organic EL element driving TFT and a pixel selecting TFT are omitted. The same numerals are provided to the same components as those of FIG. 1. In this organic EL display device, an orange emissive layer 6c is substituted for the yellow emissive layer 6b used in the first embodiment. The white emissive layer 20 is formed by laminating the blue emissive layer 6a and the orange emissive layer 6c. The blue emissive layer 6a emitting blue light having a short wavelength is formed on the side closer to the anode layer 4 which is on the light emitting side, and the orange emissive layer 6c emitting orange light having a longer wavelength than the blue light is placed on the blue emissive layer 6a. The orange emissive layer 6c is made by adding 5,12-Bis(4-(benzothiazol-2-yl)phenyl)-6,11-diphenylnaphthacene as an orange dopant to NPB (host).

Under this configuration, the blue light emitted from the blue emissive layer 6a reaches the color filter layer 3 without passing through the orange emissive layer 6c, and is emitted outside through the color filter layer 3. On the other hand, the orange light emitted from the orange emissive layer 6c passes through the blue emissive layer 6a and then the color filter layer 3. Since the orange light has a longer wavelength than the blue light, the absorption amount of the orange light is relatively small. The absorption amount of the blue light also reduces so that the luminous efficiency is improved.

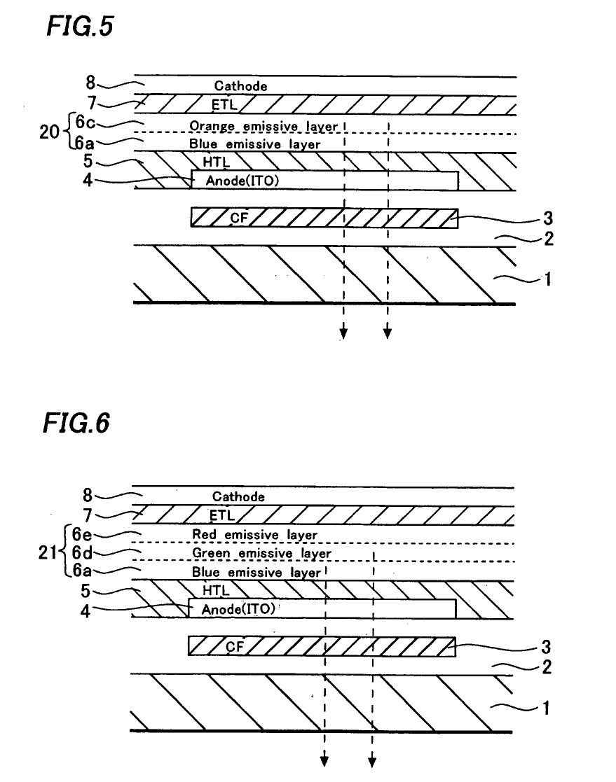

FIG. 6 is a cross-sectional view of an organic EL display device of a third embodiment. FIG. 6 shows only an organic EL element and a color filter layer in a pixel, and other components including an organic EL element driving TFT and a pixel selecting TFT are omitted. The same numerals are provided to the same components as those of FIG. 1. In this organic EL display device, the white emissive layer 21 is formed by laminating the blue emissive layer 6a, a green emissive layer 6d and a red emissive layer 6e. The blue emissive layer 6a emitting blue light having a short wavelength is formed on the side closer to the anode layer 4, and the green emissive layer 6d emitting green light having a longer wavelength than the blue light is formed on the blue emissive layer 6a. Furthermore, the red emissive layer 6e emitting red light having longer wavelength than the green light is formed on the green emissive layer 6d.

The green emissive layer 6d is made by adding 5,12-diphenylnaphthacene as a green dopant to NPB (host). The red emissive layer 6e is made by adding 6,13-diphenylpentacene as a red dopant to NPB (host).

Under this configuration, the blue light emitted from the blue emissive layer 6a reaches the color filter layer 3 without passing through the other emissive layers, and is emitted outside through the color filter layer 3. On the other hand, the green light emitted from the green emissive layer 6d passes through the blue emissive layer 6a and then the color filter layer 3. Since the green light has a longer wavelength than the blue light, the absorption amount of the green light is relatively small. Furthermore, the red light emitted from the red emissive layer 6e passes through the green emissive layer 6d and the blue emissive layer 6a, and then through the color filter layer 3. Since the red light has a longer wavelength than the green light, the absorption amount of the red light is relatively small. Therefore, under this configuration, too, the absorption amount of the blue light also reduces so that the luminous efficiency is improved.

As apparent from the first, second, third embodiments, the invention includes a display device having a plurality of emissive layers each emitting light of different wavelength. That is, by laminating the plurality of emissive layers in increasing order of wavelength of emitting light on a light emitting side, the absorption amount of light having a short wavelength can be minimized.

Furthermore, in an organic EL display device of a fourth embodiment, the red emissive layer 6e is substituted for the orange emissive layer 6c used in the second embodiment. In this embodiment, too, the blue light emitted from the blue emissive layer 6a reaches the color filter layer 3 without passing through the red emissive layer 6e, and is emitted outside through the color filter layer 3. On the other hand, the red light emitted from the red emissive layer 6e passes through the blue emissive layer 6a and then the color filter layer 3. Since the red light has a longer wavelength than the blue light, the absorption amount of the red light is relatively small. The absorption amount of the blue light also reduces so that the luminous efficiency is improved.

What is claimed is:

1. An electroluminescent display device comprising:
a plurality of pixels;
an anode layer provided for each of the pixels;
an electroluminescent layer provided for each of the pixels and disposed above a corresponding anode layer, the electroluminescent layer comprising a first emissive layer of a first wavelength and a second emissive layer of a second wavelength that is longer than the first wavelength, and the first emissive layer being disposed closer to the anode layer than the second emissive layer; and
a cathode layer disposed above the electroluminescent layers.

2. The electroluminescent display device of claim 1, further comprising a color filter layer disposed so that light emitted from the electroluminescent layer passes through the color filter layer.

3. An electroluminescent display device comprising:
an insulating substrate;
a plurality of pixels disposed on the insulating substrate;
a color filter layer provided for each of the pixels, the color filter layers being disposed above the insulating substrate;
an anode layer made of a transparent electrode, provided for each of the pixels and disposed above a corresponding color filter layer;
an electroluminescent layer provided for each of the pixels and disposed above a corresponding anode layer, the electroluminescent layer comprising a plurality of emissive layers each emitting light of a different wavelength, the emissive layers being disposed so that an emissive layer emitting light of a shorter wavelength is disposed closer to the anode layer than an emissive layer emitting light of a longer wavelength; and
a cathode layer disposed above the electroluminescent layers.

4. The electroluminescent display device of claim 3, further comprising a color filter layer disposed so that light emitted from the electroluminescent layer passes through the color filter layer.

5. The electroluminescent display device of claim 3, wherein the plurality of the emissive layers comprises a blue emissive layer and a yellow emissive layer, and the blue emissive layer is disposed closer to the anode layer than the yellow emissive layer.

6. The electroluminescent display device of claim 3, wherein the plurality of the emissive layers comprises a blue emissive layer and an orange emissive layer, and the blue emissive layer is disposed closer to the anode layer than the orange emissive layer.

7. The electroluminescent display device of claim 3, wherein the plurality of the emissive layers comprises a blue emissive layer, a green emissive layer and a red emissive layer, and the blue emissive layer is disposed on an anode side, the rend emissive layer is disposed on a cathode side and the green emissive layer is disposed between the blue and red emissive layers.

8. The electroluminescent display device of claim 3, wherein the plurality of the emissive layers comprises a blue emissive layer and a red emissive layer, and the blue emissive layer is disposed closer to the anode layer than the red emissive layer.
